(19) United States
(12) Patent Application Publication
(10) Pub. No.: US 2006/0285399 A1
(43) Pub. Date: Dec. 21, 2006

(54) Drive circuit and display apparatus

(75) Inventor: Takashi Iwami, Chuo-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION

(21) Appl. No.: 11/453,865

(22) Filed: Jun. 16, 2006

(30) Foreign Application Priority Data
Jun. 20, 2005 (JP) 2005-179456

(51) Int. Cl. G11C 7/10

(52) U.S. Cl. 365/189.01

(57) ABSTRACT

Disclosed is a drive circuit that is capable of increasing the efficiency of power recovery by improving the drive capability of a switching element of an output circuit for driving a capacitive load, particularly the drive capability in a low voltage range. The drive circuit includes a totem-pole circuit having a totem-pole structure that first and second switching elements that are n-channel transistors are series connected, a power recovery circuit connected to the other controlled electrode of the first switching element and for charging and discharging electricity to and from the capacitive load Cp through the totem-pole circuit, and an output control circuit for controlling a switching of the first and second switching elements.

### BACKGROUND OF THE INVENTION

1. Field of the Invention

The present invention relates to a drive circuit for driving the display cells of a display apparatus, such as a plasma display as a capacitive load, and more particularly to a drive circuit having a power recovery circuit that recovers and reuses the charge stored on the capacitive load.

2. Description of the Related Art

Power devices, such as MOSFETs (MOS field-effect transistors) or IGBTs (insulated-gate bipolar transistors), are widely used as switching elements to drive display cells of a display such as a liquid-crystal display, an organic EL display or a plasma display. For example, the plasma display is formed with a discharge space in which discharge gas is sealed between a front glass substrate and a back substrate that are opposed to each other. On an inner surface of the front glass substrate a plurality of row electrode pairs are formed. Each of the row electrode pairs is constituted by two strip electrodes extending in a row direction. On an inner surface of the back substrate a plurality of strip column electrodes are formed extending in a column direction. In the areas corresponding to intersections of the row electrode pairs with the column electrodes, a plurality of display cells (i.e., discharge cells) are formed. The display cells include phosphor coatings on the inside of the display cells, and partition the discharge space into a plurality of regions. When displaying an image on such a plasma display, a drive circuit applies address pulses at a high voltage to the display cells through the column electrodes, to thereby selectively produce wall charges within the display cells. Thereafter, the drive circuit applies discharge-sustain pulses repeatedly to the display cells through the row electrode pairs. As a result, gas discharges (sustain discharges) take place in the display cells in which thee wall charges are formed. Ultraviolet rays are created by the gas discharges, and cause the phosphors in the display cells to excite to emit light. The related art as to a plasma display of this kind is disclosed, for example, in Japanese Patent Kokai No. 2004-4606 (or the corresponding U.S. patent application Publication No. 2003/193451).

The plasma display, in most cases, is mounted with a power recovery circuit that is capable of recovering charge (i.e., ineffective charge) stored on the display cells that are capacitive loads, and of reusing the recovered charge in order to save consumption power. The related art concerning the power recovery circuit of this kind is disclosed, for example, in Japanese Patent No. 2946921. FIG. 1 is a diagram schematically showing a part of a configuration of a drive circuit 100 having a power recovery circuit which is disclosed in the Japanese Patent No. 2946921. The drive circuit 100 has a power recovery circuit 105 and an output circuit 101. The output circuit 101 is connected to a capacitive load Cp that is a display cell, through electrodes.

The power recovery circuit 105 includes a p-channel MOS transistor PR1, diodes R1, R2, and an n-channel MOS transistor NR1. Those elements PR1, R1, R2 and NR1 are connected in series. Parasitic diodes DR1, DR3 are respectively formed in the p-channel and n-channel MOS transistors PR1, NR1. The p-channel and n-channel MOS transistors PR1, NR1 have respective sources connected to one end of a neutral capacitor Ci. The other end of the neutral capacitor Ci is connected to a ground potential. The neutral capacitor Ci is a power recovery capacitor having a very high capacity as compared to the capacitive load Cp, to function as a voltage source. The power recovery circuit 105 includes a p-channel MOS transistor PR2 and an n-channel MOS transistor NR2 that are connected in series. Parasitic diodes DR2, DR4 are respectively formed in the p-channel MOS transistor PR2 and the n-channel MOS transistor NR2. The p-channel MOS transistor PR2 has a source connected to a power-source potential VDD while the n-channel MOS transistor NR2 has a source connected to a ground potential. Furthermore, an inductor Li has one end connected to the diodes R1, R2 and has the other end connected to drains of the p-channel and n-channel MOS transistors PR2, NR2 and to an input/output terminal T1. The MOS transistors PR1, PR2, NR1 and NR2 are enhancement MOSFETs (enhancement-mode metal-oxide-semiconductor field-effect transistors).

On the other hand, the output circuit 101 has a pre-buffer circuit 102, a level-shift circuit 103 and a push-pull circuit 104. The level-shift circuit 103 is configured by n-channel MOS transistors NM1, NM2 and p-channel MOS transistors PM1, PM2. The push-pull circuit 104 that has a CMOS structure (complementary metal-oxide-semiconductor structure) is configured by series-connected p-channel and n-channel MOS transistors PM3, NM3. Parasitic diodes DO1, DO2 are respectively formed in the MOS transistors PM3, NM3. The p-channel MOS transistor PM3 has a source connected to an input/output terminal T2 that is connected to an input/output terminal T1 of the power recovery circuit 105. The n-channel MOS transistor NM3 has a source connected to a ground potential. The pre-buffer circuit 102 is a logic gate circuit that generates voltages to be applied to the MOS transistors NM1, NM2 and NM3 in accordance with an input signal voltage V_{IN}.

Operation of the drive circuit 100 will be described. When no pulse is applied to the capacitive load Cp, an input signal voltage V_{IN} having a logic value “0” is provided to the pre-buffer circuit 102. According to the input signal voltage V_{IN}, the pre-buffer circuit 102 supplies the MOS transistor NM2 with a gate voltage to turn off, and the MOS transistor NM1, NM3 with a gate voltage to turn on. In this case, because the p-channel MOS transistor PM3 is not conductive but the n-channel MOS transistor NM3 is conductive, the output voltage to the capacitive load Cp is at the ground potential.

When raising the output voltage to the capacitive load Cp, an input signal voltage V_{IN} having a logic value “1” is provided to the pre-buffer circuit 102. According to the input signal voltage V_{IN}, the pre-buffer circuit 102 supplies the MOS transistor NM2 with a gate voltage to turn on, and the MOS transistor NM1, NM3 with a gate voltage to turn off. As a result, the n-channel MOS transistor NM3 is not conductive, but the p-channel MOS transistor PM3 turns on and becomes conductive. In this case, as shown in FIGS. 2A to 2E, when a gate voltage is applied at time to turn on the p-channel MOS transistor PR1 of the power recovery circuit 105, an LC resonant circuit is constituted by the inductor Li and the capacitive load Cp. By operation of the LC resonant circuit, a drive current (charge) is supplied from the neutral capacitor Ci to the capacitive load Cp through the MOS transistor PR1, the diode R1, the inductor Li and the p-channel MOS transistor PM3. As a result, the output voltage level starts rising from the ground potential. Thereafter, when a gate voltage is applied to turn on the p-channel MOS transistor PR2 at time t1, the output voltage is clamped at the power-source potential VDD.

Meanwhile, when lowering the output voltage, gate voltages are applied at time t2 to turn off the p-channel MOS transistor PR1, PR2, and to turn on the n-channel MOS transistor NR1, as shown in FIGS. 2A to 2E. As a result, the charge stored on the capacitive load Cp is recovered to the neutral capacitor Ci through the MOS transistor PM3, the inductor Li, the diode R2 and the MOS transistor NR1. Thus, the capacitive load Cp discharges electricity and hence the output voltage starts falling down from the power-source potential VDD. Thereafter, when applied a gate voltage to turn on the n-channel MOS transistor NR2 at time t3, the output voltage is clamped at the ground potential.

In the drive circuit 100, the efficiency of power recovery relies upon the output characteristic, i.e. drive capability, of the MOS transistor PM3 at the higher voltage side of the push-pull circuit 104. In a low voltage range where the voltage supplied from the power recovery circuit 105 to the push-pull circuit 104 is low, the p-channel MOS transistor PM3 has an on-resistance higher as compared to that in a high voltage range, and hence an amount of drive current becomes smaller. This causes a problem in reducing the efficiency of power recovery. In order to increase the drive current in the low voltage range, the p-channel MOS transistor PM3 may be formed on a larger device area. However, such an increase of the device area incurs an increase in chip size of the output circuit 101, and thus is a factor in increasing the manufacturing cost.

Furthermore, the p-channel MOS transistor PM3 generates considerable heat caused by on-resistance of the p-channel MOS transistor PM3 because of its switch operation at high speed. Accordingly, there is a problem that a heat-dissipation configuration is large in scale and thus is a factor in increasing the manufacturing cost.

### SUMMARY OF THE INVENTION

In view of the foregoing, it is an object of the present invention to provide a drive circuit and display apparatus that are capable of increasing the efficiency of power recovery by improving drive capability of switching elements of an output circuit that drives capacitive loads, particularly by improving the drive capability in a low voltage range.

According to a first aspect of the present invention, there is provided a drive circuit for driving display cells that are capacitive loads, in response to an input signal voltage. The drive circuit comprises: a totem-pole circuit having a totem-pole structure in which first and second switching elements that are n-channel transistors are series connected, both one of controlled electrodes of the first switching element and one of controlled electrodes of the second switching element being commonly connected to the capacitive loads, and the other controlled electrode of the second switching element being connected to a reference potential; a power recovery circuit connected to the other controlled electrode of the first switching element for charging and discharging electricity to and from the capacitive loads through the totem-pole circuit; and an output control circuit for generating control voltages to be provided to the respective first and second switching elements in accordance with the input signal voltage thereby to control switching of the first and second switching elements.

According to a second aspect of the present invention, there is provided a display apparatus comprising a plurality of display cells arranged in a planar form; a plurality of electrodes connected to the plurality of display cells; and a drive circuit for driving the plurality of display cells that are capacitive loads through the plurality of electrodes in response to an input signal voltage. The drive circuit includes: a totem-pole circuit having a totem-pole structure in which first and second switching elements that are n-channel transistors are series connected, both one of controlled electrodes of the first switching element and one of controlled electrodes of the second switching element being commonly connected to the capacitive loads, and the other controlled electrode of the second switching element being connected to a reference potential; a power recovery circuit connected to the other controlled electrode of the first switching element for charging and discharging electricity to and from the capacitive loads through the totem-pole circuit; and an output control circuit for generating control voltages to be provided to the first and second switching elements in accordance with the input signal voltage thereby to control switching of the first and second switching elements.

According to a third aspect of the present invention, there is provided a drive circuit for driving display cells that are capacitive loads, in response to an input signal voltage. The drive circuit comprises: a totem-pole circuit having a totem-pole structure in which first and second switching elements that are npn transistors are series connected, both an emitter of the first switching element and a collector of the second switching element being commonly connected to the capacitive loads, and an emitter of the second switching element being connected to a reference potential; a power recovery circuit connected to a collector of the first switching element for charging and discharging electricity to and from the capacitive loads through the totem-pole circuit; and an output control circuit for generating current signals to be provided to the respective first and second switching elements in accordance with the input signal voltage thereby to control switching of the first and second switching elements.

Further features of the invention, its nature and various advantages will be more apparent from the accompanying drawings and the following detailed description of the preferred embodiments.

### BRIEF DESCRIPTION OF THE DRAWINGS

FIG. 1 is a diagram schematically showing a part of a configuration of a drive circuit having a conventional power recovery circuit;

FIGS. 2A to 2E are timing charts illustrating operation of the drive circuit shown in FIG. 1;

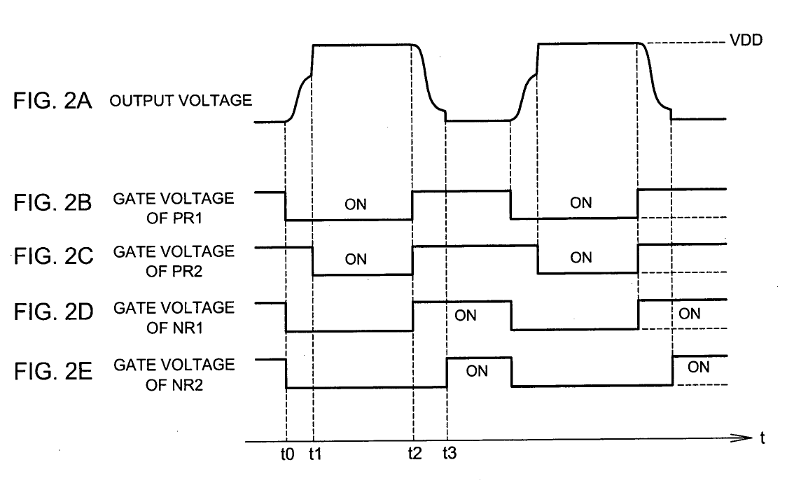

FIG. 3 is a diagram schematically showing a configuration of a display apparatus (plasma display) according to an embodiment of the present invention;

FIG. 4 is a diagram showing a configuration of a column-electrode driver (address driver);

FIG. 5 is a schematic diagram showing an example of an output circuit constituting a pulse generation circuit;

FIG. 6 schematically illustrates an example of a drive sequence; and

FIG. 7 is a graphical representation showing MOS transistor characteristics.

### DETAILED DESCRIPTION OF THE INVENTION

With reference to the drawings, various embodiments of the present invention will now be described.

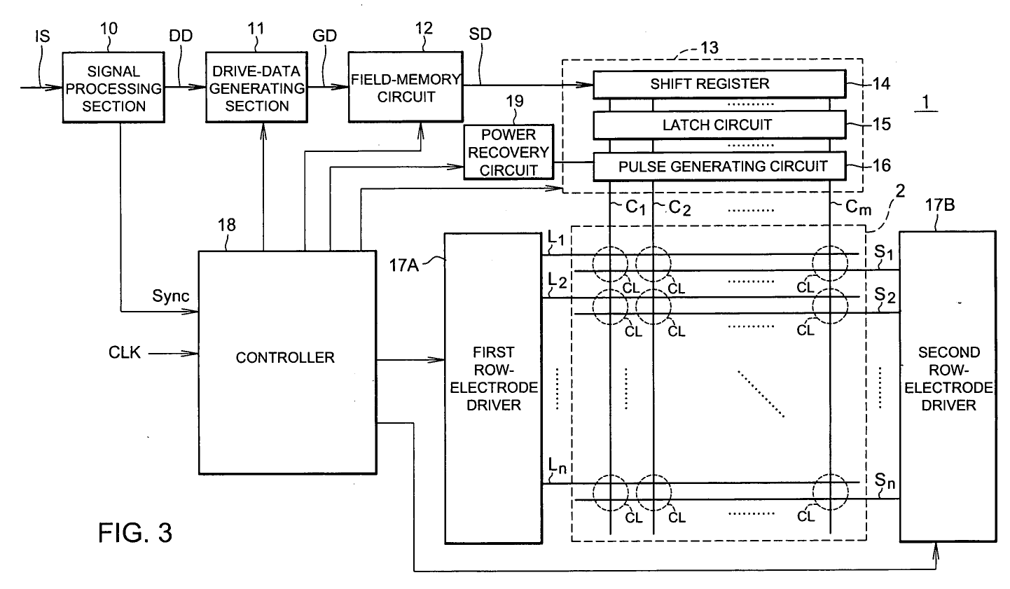

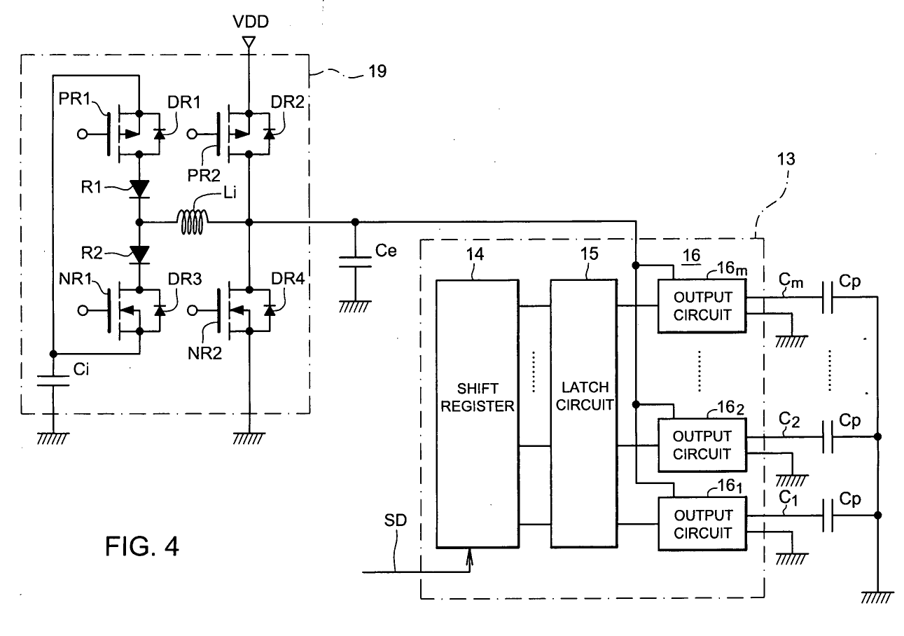

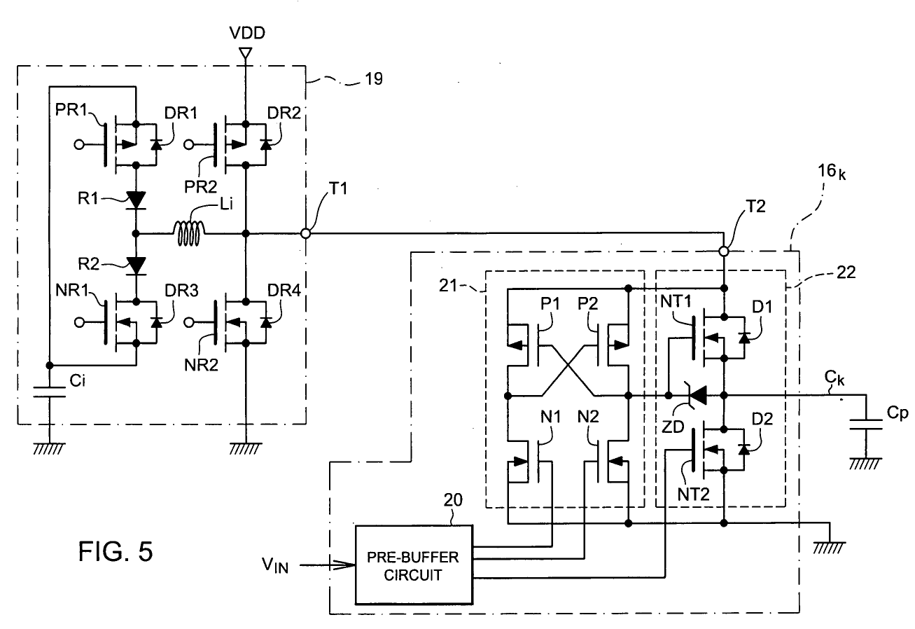

FIG. 3 is a diagram schematically showing a configuration of a display apparatus (plasma display) 1 according to an embodiment of the present invention. FIG. 4 is a schematic diagram showing a configuration of a column-electrode driver (address driver) 13. FIG. 5 is a schematic diagram showing an example of an output circuit constituting a pulse generation circuit 16.

Referring to FIG. 3, a display apparatus 1 includes a signal processing section 10, a drive-data generating section 11, a field memory circuit 12, a column-electrode driver 13, a first row-electrode driver 17A, a second row-electrode driver 17B and a controller 18. The controller 18 generates control signals with which the processing blocks 11, 12, 13, 17A, 17B are controlled in operation, by using a synchronization signal (including horizontal and vertical synchronization signals) Sync and clock signal CLK supplied thereto. The controller 18 supplies the control signals to the processing blocks.

The display apparatus 1 has a display region 2 including a plurality of display cells CL arranged in a planar and matrix form. In the display region 2, there are formed n-number of row electrodes L₁, . . . , Lₙ (n is an integer equal to or greater than 2) extending horizontally from the first row-electrode driver 17A and n-number of row electrodes S₁, . . . , Sₙ extending horizontally from the second row-electrode driver 17B opposed to the first row-electrode driver 17A through the display region 2. Two row electrodes L_{q}, S_{q} (q is an integer of 1 to n) constitutes one row-electrode pair, to form one horizontal display line along each of the row electrode pairs. There are formed m-number of column electrodes C₁, . . . , Cₘ (m is an integer of 2 or greater) extending vertically from the column-electrode driver 13. The column electrodes Cp (p is an integer of 1 to m) is isolated from the low electrode pairs L_{q}, S_{q} in the thickness direction of a substrate (not shown). Display cells CL are formed at respective areas corresponding to the intersections of the column electrodes Cₚ with the row electrode pairs L_{q}, S_{q}. Each display cell CL has a discharge space between the row electrode pair L_{q}, S_{q} and. the column electrode Dₚ. The discharge spaces are applied with respective phosphors each having an emission color in any one of R (red), G (green) and B (blue).

The signal processing section 10 performs image processing on an input video signal IS and generates a synchronization signal Sync and digital-image signal DD, to supply the synchronization signal Sync to the controller 18 and the digital-image signal DD to the drive-data generating section 11. The drive-data generating section 11 converts the digital-image signal DD into a drive-data signal GD according to a predetermined format, and supplies the drive-data signal GD to a field-memory circuit 12. The field-memory circuit 12 temporarily stores the drive-data signal GD in an internal buffer memory (not shown), while reading sequentially the sub-field signals SD in units of sub-field from the internal buffer memory to transfer the signals SD in order to the column-electrode driver 13.

The column-electrode driver 13 has an m-bit shift register 14, a latch circuit 15 and a pulse generating circuit 16. The column-electrode driver 13 operates in accordance with a control signal and a clock signal from the controller 18. The pulse generating circuit 16 is connected with a power recovery circuit 19 that operates in accordance with a control signal from the controller 18. The shift register 14 fetches a transferred sub-field signal SD in response to a pulse edge of a shift clock, and shifts the fetched sub-field signals SD. The shift register 14 supplies, in parallel, the shifted signals in an amount of one horizontal line to the latch circuit 15. The latch circuit 15 latches the output signals from the shift register 14 and supplies, in parallel, the latched signals to the pulse generating circuit 16. The pulse generating circuit 16 generates drive pulses such as an address pulse based on the output signals from the latch circuit 15, and supplies the drive pulses to the display cells CL through the column electrodes C₁, . . . , Cₘ, respectively. The configuration of the pulse generating circuit 16 and power recovery circuit 19 will be described later.

The first row-electrode driver 17A is configured with a drive circuit that generates a scanning pulse in synchronization with an address pulse; and a drive circuit that generates discharge-sustain pulses. The second row-electrode driver 17B is a drive circuit that generates discharge-sustain pulses.

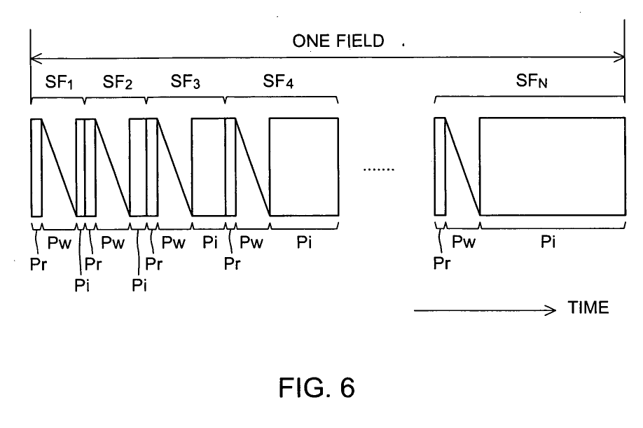

The controller 18 is capable of controlling operations of the drivers 13, 17A and 17B in accordance with a predetermined drive sequence. The drive sequence is schematically shown in FIG. 6 as an example. Referring to FIG. 6, one field period of display data is comprised of M-number of sub-field periods SF₁-SF_{M} (M is an integer equal to or greater than 2) arranged successively in the order of display events. Each of the sub-fields SF₁-SF_{M} has a reset period Pr, an address period Pw and a sustain period Pi. The sub-fields SF₁, SF₂, SF₃ . . . , SF_{M} are respectively assigned with emission sustain periods Pi that are proportional to respective weights 2⁰, 2¹, 2², . . . , 2^{M}.

In the reset period Pr of the sub-field SF₁, reset discharge is caused in all the display cells CL to erase wall charges interior of all the display cells CL, thus initializing all the display cells CL. In the following address period Pw, the first row-electrode driver 17A applies scanning pulses sequentially to the row electrodes L₁-Lₙ while the column-electrode driver 13 applies address pulses in synchronization with the scanning pulses to the address electrodes C₁, . . . , Cₘ. As a result, address discharges (write address discharges) are selectively caused in the display cells CL, thus forming wall charges selectively. In the sustain period Pi, the first row-electrode and second row-electrode drivers 17A, 17B apply discharge-sustain pulses mutually different in polarity repeatedly the assigned number of times to the sustain electrodes L₁, . . . , Lₙ and S₁, . . . , Sₙ. As a result, sustain discharges take place repeatedly in the display cells CL where wall charges are stored, thus exciting the phosphors interior of the display cells CL and causing light emissions therein. In each of the following sub-fields SF₁-SF_{M}, the display cells CL are initialized in the reset period Pr. Address discharges (write address discharges) are caused selectively in the display cells CL in the address period Pw, thus selectively forming a wall charge therein. In the sustain period Pi, sustain discharges are caused in the display cells CL where wall charges are stored, repeatedly the assigned number of times to the corresponding sub-field. The drive sequence described above allows for display with 2^{M} grayscale levels.

Incidentally, the drive sequence is not limited to that of FIG. 6. In place of the drive sequence, other drive sequences may be employed and hereby incorporated by reference to Japanese Patent Kokai No. 2000-227778 and the corresponding U.S. patent application Publication No. 2002/054000 (or U.S. Pat. No. 6614413).

Referring to FIGS. 4 and 5, the configuration of the column-electrode driver 13 will now be described. In FIG. 4, the pulse generating circuit 16 has output circuits 16₁, . . . , 16ₘ respectively connected to the column electrodes C₁, . . . , Cₘ. The output circuits 16₁, . . . , 16ₘ are respectively connected to capacitive loads Cₚ through the column electrodes C₁, . . . , Cₘ. The output circuits 16₁, . . . , 16ₘ generate drive pulses such as address pulses in accordance with signal voltages outputted in parallel from the latch circuit 15. The output circuit 16₁, . . . , 16ₘ are connected to the power recovery circuit 19 through a line having a capacitor Ce between the terminals T1, T2.

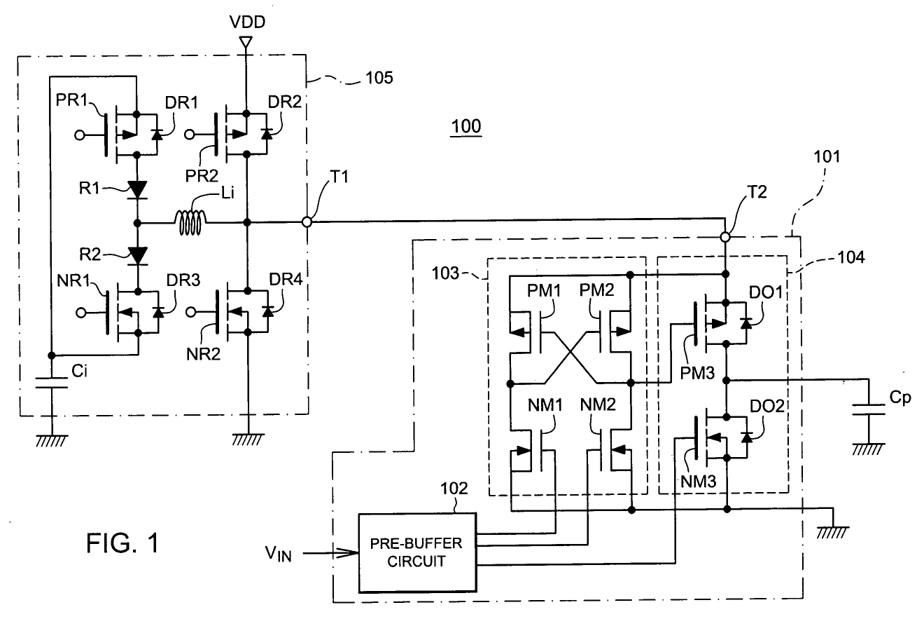

The power recovery circuit 19 has substantially the same configuration as the power recovery circuit 105 shown in FIG. 1. In FIGS. 1 and 4, elements with the same reference number have the same function and hence the detailed description is omitted. Note that a configuration of the power recovery circuit 19 is not limited to the configuration shown in FIG. 4.

Referring to FIG. 5, the output circuit 16ₖ (k is an integer of 1 to m) has a pre-buffer circuit 20, a level-shift circuit 21 and a totem-pole circuit 22. The level-shift circuit 21 is configured with a first CMOS circuit (complementary MOS circuit) formed by a series connected n-channel MOS transistor N1 and p-channel MOS transistor P1, and a second CMOS circuit formed by a series connected n-channel MOS transistor N2 and p-channel MOS transistor P2. The p-channel MOS transistors P1, P2 have sources (controlled electrodes) commonly connected to the power recovery circuit 19 that is a high voltage source. The n-channel MOS transistors N1, N2 have sources (controlled electrodes) both connected to a reference potential, i.e. a ground potential. One p-channel MOS transistor P1 has a gate (controlling electrode) connected to a drain (controlled electrode) of the other p-channel MOS transistor P2 and to a drain (controlled electrode) of the n-channel MOS transistor N2. The other p-channel MOS transistor P2 has a gate (controlling electrode) connected to a drain (controlled electrode) of the one p-channel MOS transistor P1 and to a drain (controlled electrode) of the n-channel MOS transistor N1.

The totem-pole circuit 22 is configured with a high-voltage n-channel MOS field-effect transistor (first switching element) NT1 arranged on a higher voltage side, a voltage-regulation diode ZD connected between a gate and a source (between controlling and controlled electrodes) of the n-channel MOS transistor NT1, and a high-voltage n-channel MOS field-effect transistor (second switching element) NT2 arranged on a lower voltage side. The MOS transistors NT1, NT2 are respectively formed with parasitic diodes D1, D2. The connection line between the high-Voltage MOS transistors NT1, NT2 is connected to the capacitive load Cp through the column electrode Cₖ. Meanwhile, the MOS transistor NT2 arranged on the lower voltage side has a source (controlled electrode) connected to a reference potential, i.e., the ground potential, while the MOS transistor NT1 arranged on the higher voltage side has a drain (controlled electrode) connected to the power recovery circuit 19 that is a high voltage source. Incidentally, both the MOS transistors NT1, NT2 may be enhancement-type MOSFETs.

The voltage-regulation diode ZD, configured by a Zener diode for example, is connected between the source (controlled electrode) and gate (controlling electrode) of the n-channel MOS transistor NT1 such that the forward direction of the diode ZD is from the source to the gate. The voltage-regulation diode ZD is a protection diode operable to prevent the application of an excessive voltage to the gate of the n-channel MOS transistor NT1.

The totem-pole circuit 22 has so-called a totem-pole structure constituted by the n-channel MOS transistors NT1, NT2 that are the same switching elements and connected in series. Those n-channel MOS transistors NT1, NT2 are both switching elements that turn on to be conductive in response to a control voltage of a predetermined level. Here, the control voltage means a source-to-gate voltage.

Incidentally, the MOS transistors NT1, NT2 of the totem-pole circuit 22 are preferably both MOSFETs as shown in FIG. 5, no limitation thereto intended. For example, only the transistor NT1 on the higher voltage side may be implemented with an IGBT (insulated-gate bipolar transistor) that becomes conductive in response to a control voltage of a predetermined level applied between a gate and an emitter thereof. Alternatively, both the transistors NT1, NT2 on the higher and lower voltage sides may be implemented with IGBTs.

In place of the MOS transistors NT1, NT2, npn bipolar transistors may be used that are switching elements operable depending on current. In this case, the bipolar transistor on the higher voltage side at its collector is connected to the power recovery circuit 19, the bipolar transistor on the higher voltage side at its emitter and the bipolar transistor on the lower voltage side at its collector are commonly connected to the capacitive load Cp. The bipolar transistor on the lower voltage side at its emitter is connected to a reference potential.

A pre-buffer circuit 20 is a logic gate circuit that generates voltages to be applied to the gates of the n-channel MOS transistors N1, N2 and the gate of high-voltage n-channel MOS transistor NT2, in accordance with an input signal voltage from the latch circuit 15.

The output circuit 16ₖ operates as in the following manner. When a drive pulse is not applied to the capacitive load Cp, the pre-buffer circuit 20 supplies a gate voltage to turn on the n-channel MOS transistor NT2, and supplies a gate voltage to turn off the n-channel MOS transistor N1 and to turn on the n-channel MOS transistor N2, according to an input signal voltage V_{IN} having a logic value of “0”. As a result, because the n-channel MOS transistor NT1 on the higher voltage side becomes non-conductive while the n-channel MOS transistor NT2 on the lower voltage side becomes conductive, the output voltage to the capacitive load Cp is given as a reference potential.

When raising the output voltage to the capacitive load Cp, the pre-buffer circuit 20 supplies a gate voltage to turn on the n-channel MOS transistor N1 and off the n-channel MOS transistor N2, and a gate voltage to turn off the n-channel MOS transistor NT2, according to an input signal voltage V_{IN} changing in logic value from “0” to “1”. As a result, the n-channel MOS transistor NT1 on the higher voltage side turns on and becomes conductive. Thus, an LC resonant circuit is established by the inductor Li of the power recovery circuit 19 and the capacitive load Cp. By operation of the LC resonant circuit, drive current (charges) is supplied from the neutral capacitor Ci to the capacitive load Cp through the p-channel MOS transistor PR1, the diode R1, the inductor Li and the n-channel MOS transistor NT1. Thus, the output voltage level starts to rise from the reference potential. Thereafter, when applied a gate voltage causing the p-channel MOS transistor PR2 to turn on, the output voltage is clamped at the power-source potential VDD.

On the other hand, when lowering the output voltage, a gate voltage causing the p-channel MOS transistors PR1, PR2 of the power recovery circuit 19 to turn off is applied, and a gate voltage causing the n-channel MOS transistor NR1 to turn on is applied. As a result, the charges stored on the capacitive load Cₚ is recovered to the neutral capacitor Ci through the n-channel MOS transistor NT1, the inductor Li, the diode R2 and the n-channel MOS transistor NR1. Accordingly, the capacitive load Cₚ discharges electricity and the output voltage begins to lower in level from the power-source potential VDD. Thereafter, when applied a gate voltage causing the n-channel MOS transistor NR2 of the power recovery circuit 19 to turn on, the output voltage is clamped at the reference potential.

According to the output circuit 16ₖ, even in the lower voltage range where a low voltage is supplied to the drain of the n-channel MOS transistor NT1 upon raising or lowering the output voltage, the n-channel MOS transistor NT1 is capable of having a low on-resistance and exhibiting a high drive capability. This makes it possible to greatly prevent the reduction in the source-to-drain drive current.

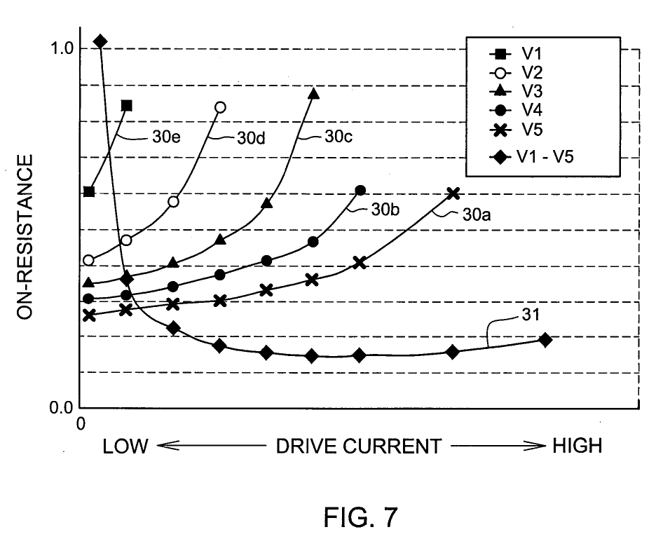

FIG. 7 is a graphical representation showing characteristics of the p-channel MOS transistor PM3 of the output circuit 101 shown in FIG. 1, and characteristics of the n-channel MOS transistor NT1 of the output circuit ¹⁶k according to the present embodiment shown in FIG. 5. The coordinate axis of the graph represents a measurement value of source-to-drain drive current while the ordinate axis a measurement value of on-resistance. The on-resistance measurement values are normalized in a predetermined range. In the graph, the curves 30a, 30b, 30c, 30d and 30e show respectively the characteristics of the p-channel MOS transistor PM3 (shown in FIG. 1) of the push-pull circuit 104 where the power-source voltage is the values of V5, V4, V3, V2 and V1 (V5>V4>V3>V2>V1) while the curve 31 shows the characteristic of the n-channel MOS transistor NT1 (shown in FIG. 5) of the totem-pole circuit 22 where the power-source voltage is in the range of V1-V5. Here, although not described concretely, the voltages V1-V5 have values in the range from nearly 0 to several tens of milli-amperes. According to the characteristic curves 30a-30e, it can be seen that, as the power-source voltage decreases from V5 toward V1 in the transistor principal operation range (from 0 to several tens of milli-amperes), the p-channel MOS transistor PM3 of the push-pull circuit 104 has an increased on-resistance causing the source-to-drain drive current to decrease. Contrary to this, the characteristic curve 31 has a form less changing in the voltage value range of V1 to V5. It can be seen that the MOS transistor NT1 in the totem-pole circuit 22 has a relatively low on-resistance. Further, the MOS transistor NT1 maintains a stable characteristic even where the voltage changes in the principal operation range.

According to the drive circuit of this embodiment, the MOS transistor NT1 that is a switching transistor exhibits a high drive capability even in the low voltage range. This makes it possible to improve power recovery efficiency and reduce consumption power. Further, because of the capability of obtaining a sufficient amount of drive current even in the low voltage range without increasing the device area of the MOS transistor NT1, a chip can be reduced in size. Furthermore, because heat divergence is reduced in the column-electrode driver 13, a heat-dissipation configuration can be reduced in scale. Accordingly, cost reduction is possible for the display apparatus (plasma display) 1.

This application is based on Japanese Patent Application No. 2005-179456 which is hereby incorporated by reference.

What is claimed is:

1. A drive circuit for driving display cells that are capacitive loads, in response to an input signal voltage, said drive circuit comprising:
a totem-pole circuit having a totem-pole structure in which first and second switching elements that are n-channel transistors are series connected, both one of controlled electrodes of said first switching element and one of controlled electrodes of said second switching element being commonly connected to said capacitive loads, and the other controlled electrode of said second switching element being connected to a reference potential;
a power recovery circuit connected to the other controlled electrode of said first switching element for charging and discharging electricity to and from said capacitive loads through said totem-pole circuit; and
an output control circuit for generating control voltages to be provided to the respective first and second switching elements in accordance with the input signal voltage thereby to control switching of said first and second switching elements.

2. A drive circuit according to claim 1, wherein each of said first and second switching elements includes an n-channel MOS field-effect transistor.

3. A drive circuit according to claim 1, further comprising a voltage-regulation diode connected between a controlling electrode of said first switching element and one of the controlled electrodes of said first switching element.

4. A drive circuit according to claim 1, wherein said output control circuit includes a pre-buffer circuit which generates first and second control voltages depending upon the input signal voltage and provides the second control voltage to said second switching element; and a level shift circuit which converts the first control voltage and provides the converted control voltage to said first switching element.

5. A drive circuit according to claim 1, wherein said display cells are discharge cells constituting a plasma display.

6. A display apparatus comprising a plurality of display cells arranged in a planar form; a plurality of electrodes connected to said plurality of display cells; and a drive circuit for driving said plurality of display cells that are capacitive loads through said plurality of electrodes in response to an input signal voltage, said drive circuit including:
a totem-pole circuit having a totem-pole structure in which first and second switching elements that are n-channel transistors are series connected, both one of controlled electrodes of said first switching element and one of controlled electrodes of said second switching element being commonly connected to said capacitive loads, and the other controlled electrode of said second switching element being connected to a reference potential;
a power recovery circuit connected to the other controlled electrode of said first switching element for charging and discharging electricity to and from said capacitive loads through said totem-pole circuit; and
an output control circuit for generating control voltages to be provided to said first and second switching elements in accordance with the input signal voltage thereby to control switching of said first and second switching elements.

7. A display apparatus according to claim 6, wherein said drive circuit further includes a voltage regulation diode connected between a controlling electrode of said first switching element and one of the controlled electrodes of said first switching element.

8. A drive circuit for driving display cells that are capacitive loads, in response to an input signal voltage, said drive circuit comprising:
a totem-pole circuit having a totem-pole structure in which first and second switching elements that are npn transistors are series connected, both an emitter of said first switching element and a collector of said second switching element being commonly connected to said capacitive loads, and an emitter of said second switching element being connected to a reference potential;
a power recovery circuit connected to a collector of said first switching element for charging and discharging electricity to and from said capacitive loads through said totem-pole circuit; and
an output control circuit for generating current signals to be provided to the respective first and second switching elements in accordance with the input signal voltage thereby to control switching of said first and second switching elements.
